(19) United States
(12) Patent Application Publication
(10) Pub. No.: US 2026/0173340 A1
(43) Pub. Date: Jun. 18, 2026

(54) KITTING DEVICE

(71) Applicant: FUJI CORPORATION, Chiryu (JP)

(72) Inventor: Daiki SUZUKI, Toyokawa-shi (JP)

(73) Assignee: FUJI CORPORATION, Chiryu (JP)

(21) Appl. No.: 19/103,565

(22) PCT Filed: Oct. 11, 2022
(86) PCT No.: PCT/JP2022/037831

§ 371 Date: Feb. 13, 2025

(51) Int. Cl. H05K 13/02

(52) U.S. Cl. CPC H05K 13/021

(57) ABSTRACT

A kitting device sets a reel, onto which a carrier tape accommodating a component is wound, in a feeder. The kitting device includes a drum replacement unit. The drum replacement unit replaces a used drum, onto which a cover tape peeled off from the carrier tape is wound, with a replacement drum onto which the cover tape is capable of being wound.

### TECHNICAL FIELD

The present description discloses a technique related to a kitting device.

### BACKGROUND ART

A component tape replacement system described in Patent Literature 1 automatically and continuously executes work of retrieving a used component tape and a cover tape from a tape feeder and setting a component tape before use in the tape feeder. Specifically, a component tape attaching device described in Patent Literature 1 includes component tape setting means and component tape retrieving means. The component tape setting means sets the component tape before use in a first component tape storage section. The component tape retrieving means retrieves the used component tape from a second component tape storage section.

### CITATION LIST

### Patent Literature

Patent Literature 1: JP 2019-204858 A

### SUMMARY OF THE INVENTION

### Technical Problem

However, the component tape replacement system described in Patent Literature 1 does not retrieve the cover tape wound onto a drum. In configurations where the cover tape is wound on the drum, it is necessary to replace the drum.

In view of such circumstances, the present description discloses a kitting device capable of replacing a used drum in which a cover tape peeled off from a carrier tape is wound.

### Solution to Problem

The present description discloses a kitting device for setting a reel, onto which a carrier tape configured to accommodate a component is wound, in a feeder, the kitting device including a drum replacement unit. The drum replacement unit is configured to replace a used drum onto which a cover tape peeled off from the carrier tape is wound with a replacement drum onto which the cover tape is capable of being wound.

Note that, the present description discloses a technical idea where, in Claim 3 as described in the claims initially attached the application (hereinafter, refers to initial claims), the phrase “the kitting device according to Claim 1” is modified to “the kitting device according to Claim 1 or 2”. In addition, the present description discloses a technical idea in which the phrase “the kitting device according to Claim 3” in Claim 7 described in the original Claims is changed to “the kitting device according to any one of Claims 3 to 6”. In addition, the present description discloses a technical idea in which the phrase “the kitting device according to Claim 1” in Claim 8 described in the original Claims is changed to “the kitting device according to any one of Claims 1 to 7”.

In addition, the present description discloses a technical idea in which the phrase “the kitting device according to Claim 1” in Claim 12 described in the original Claims is changed to “the kitting device according to any one of Claims 1 to 11”. In addition, the present description discloses a technical idea in which the phrase “the kitting device according to Claim 1” in Claim 13 described in the original Claims is changed to “the kitting device according to any one of Claims 1 to 12”.

### Advantageous Effects of Invention

With the above kitting device, the used drum can be replaced with the replacement drum.

### BRIEF DESCRIPTION OF DRAWINGS

FIG. 1 is a perspective view illustrating an example of a setup device.

FIG. 2 is a plan view of the setup device in FIG. 1.

FIG. 3 is a perspective view illustrating an example of a feeder provided in a feeder holding section.

FIG. 4 is a plan view illustrating an example of a carrier tape.

FIG. 5 is a cross-sectional view of the carrier tape in FIG. 4.

FIG. 6 is a flowchart illustrating an example of a control procedure by the setup device.

FIG. 7 is a configuration diagram illustrating a configuration example of a mechanism related to replacement of a drum.

FIG. 8 is a perspective view illustrating an example of a drum detachable unit, a drum replacement unit, and a cover tape disposal unit.

FIG. 9 is a flowchart illustrating an example of a control procedure related to replacement of the drum.

FIG. 10 is a perspective view illustrating an example of a feeder-side holding section.

FIG. 11 is a perspective view illustrating an example of the drum.

FIG. 12 is a perspective view illustrating an example of a fixing section and a chuck portion of the drum detachable unit.

FIG. 13 is a perspective view illustrating a state after a used drum and a replacement drum are replaced by the drum detachable unit.

FIG. 14 is a perspective view illustrating an example of a cover tape disposal unit.

### DESCRIPTION OF EMBODIMENTS

### 1. Embodiment

### 1-1. Configuration Example of Kitting Device 10

Kitting device 10 sets reel 70, onto which carrier tape 72 accommodating component 91 is wound, in feeder 60. Kitting device 10 only needs to be capable of setting reel 70 in feeder 60, and may take various forms. Kitting device 10 of the embodiment is setup device 10a. Setup device 10a automatically sets reel 70 in feeder 60 such that component 91 is capable of being supplied from feeder 60. Setup device 10a may take various forms.

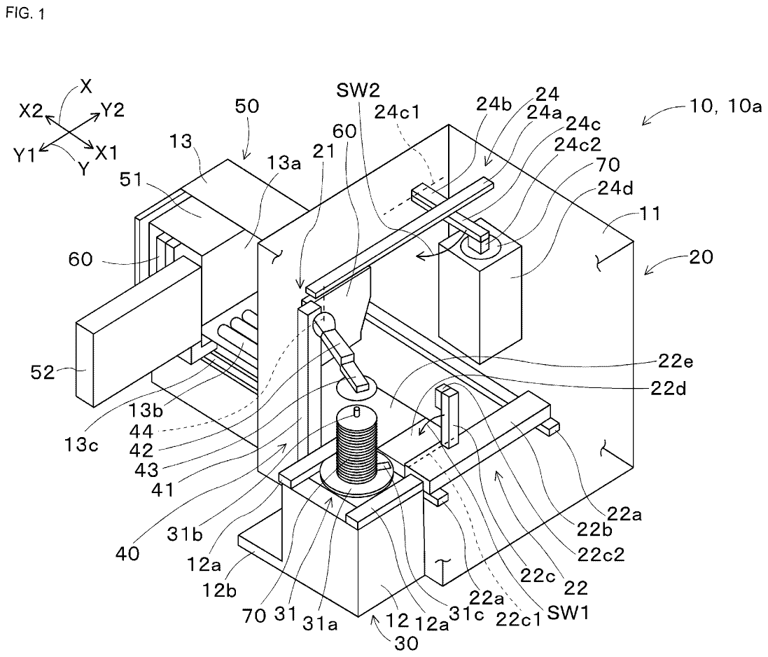

As illustrated in FIGS. 1 to 3, setup device 10a of the embodiment includes reel attachment/detachment section 20, reel supply section 30, reel transfer mechanism 40, and feeder supply section 50. For convenience of description, in the drawings, a facing direction of feeder 60 and reel 70 when reel 70 is attached to and detached from feeder 60 is referred to as a first direction (arrow X direction). In the first direction (arrow X direction), a direction (side) from feeder 60 toward reel 70 is referred to as a first end side (arrow X1 direction) in the first direction, and a direction (side) from reel 70 toward feeder 60 is referred to as a second end side (arrow X2 direction) in the first direction.

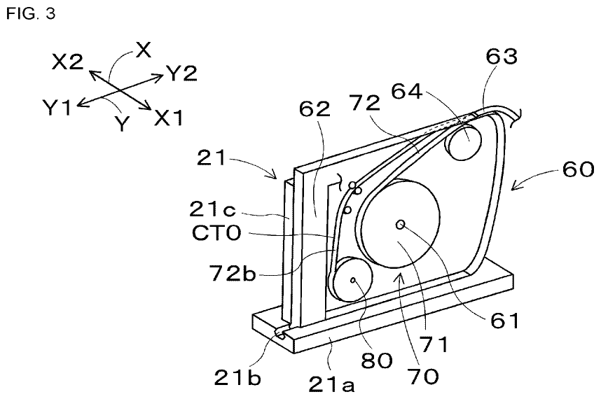

Further, as illustrated in FIG. 3, a sliding direction of feeder 60 in slot 21b, which is a direction orthogonal to the first direction (arrow X direction) in a horizontal plane, is referred to as a second direction (arrow Y direction). In the second direction (arrow Y direction), a sliding direction (side) when feeder 60 is detached is referred to as a first end side (arrow Y1 direction) in the second direction, and a sliding direction (side) when feeder 60 is attached is referred to as a second end side (arrow Y2 direction) in the second direction.

In reel attachment/detachment section 20, various members are assembled inside first housing 11. First housing 11 is a case having a rectangular parallelepiped shape, and the second end side (arrow X2 direction) in the first direction and the first end side (arrow Y1 direction) in the second direction are partially opened. Reel supply section 30 is provided to be coupled to the first end side (arrow Y1 direction) in the second direction of reel attachment/detachment section 20. Reel supply section 30 is formed in box-shaped base 12 smaller than first housing 11. Reel transfer mechanism 40 is provided on plate base 12b extending from a bottom portion of base 12 to the second end side (arrow X2 direction) in the first direction. Feeder supply section 50 is provided to be coupled to the second end side (arrow X2 direction) in the first direction of reel attachment/detachment section 20. In feeder supply section 50, various members are assembled inside second housing 13 which is smaller than first housing 11 and has storage space 13a in an upper portion.

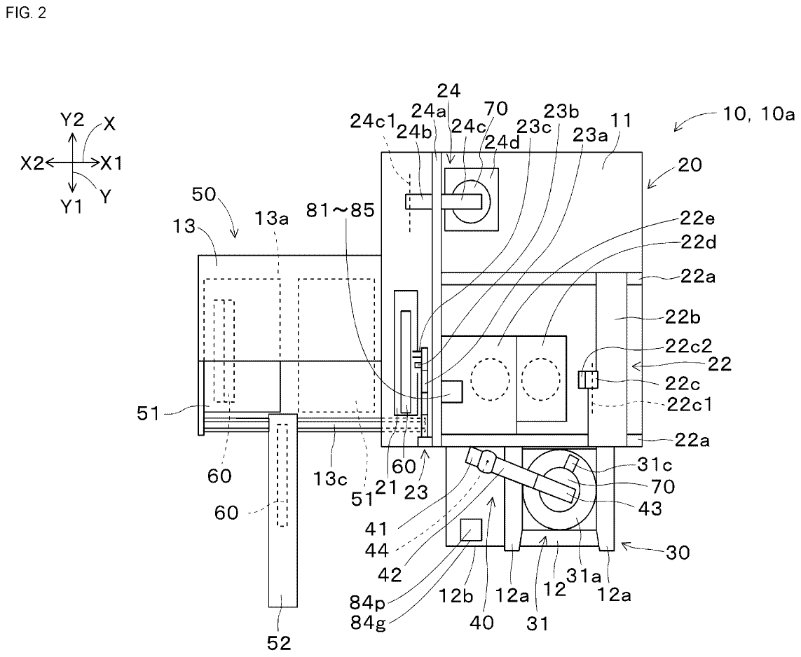

Reel attachment/detachment section 20 includes feeder holding section 21, reel attachment mechanism 22, tape loading mechanism 23, and reel detachment mechanism 24. As illustrated in FIG. 2, feeder holding section 21 is disposed on the second end side (arrow X2 direction) in the first direction and first end side (arrow Y1 direction) in the second direction inside first housing 11. Feeder holding section 21 holds feeder 60 at a work execution position in a vertical posture. As illustrated in FIG. 3, feeder holding section 21 includes bottom plate 21a, slot 21b, and support plate 21c. Slot 21b is formed in a groove shape extending along the second direction (arrow Y direction) in bottom plate 21a. Feeder 60 is inserted from the first end side (arrow Y1 direction) in the second direction of slot 21b toward the second end side (arrow Y2 direction) in the second direction thereof, and is held at the work execution position. Support plate 21c is provided to stand up from bottom plate 21a, and comes into contact with the side surface of feeder 60 at the work execution position on the second end side (arrow X2 direction) in the first direction. Support plate 21c supports a pressing load to the second end side (arrow X2 direction) in the first direction generated when reel 70 is attached to feeder 60.

Feeder 60 is detachably provided on a component mounter. As illustrated in FIG. 3, in feeder 60, reel 70, onto which carrier tape 72 is wound, is attached to main body portion 71, and carrier tape 72 is conveyed to supply component 91. An identification code for identifying reel 70 is given to each reel 70. Feeder 60 is formed in a flat box shape. Feeder 60 includes reel holding shaft 61 that protrudes from a side plate at the second end side (arrow X2 direction) in the first direction toward the first end side (arrow X1 direction) in the first direction at a substantially central position as viewed in the first direction (arrow X direction). Reel holding shaft 61 is inserted into a center hole formed at the center of reel 70, and detachably and rotatably holds reel 70.

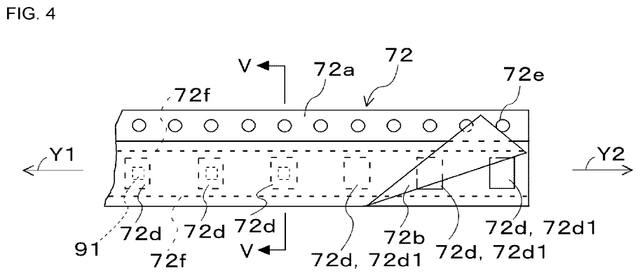

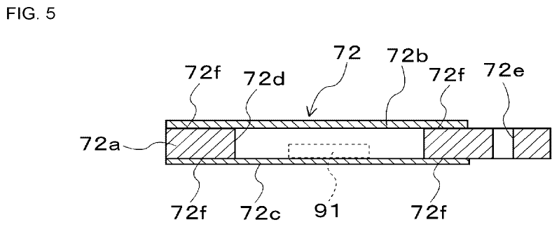

As illustrated in FIGS. 4 and 5, carrier tape 72 includes base tape 72a, cover tape 72b, and bottom tape 72c. Base tape 72a is a base portion of carrier tape 72, and is provided with multiple accommodation sections 72d and multiple feed holes 72e. Component 91 is accommodated in each of multiple accommodation sections 72d. As illustrated in FIG. 4, a predetermined number (for example, three in FIG. 4) of accommodation sections 72d from a tip end side of carrier tape 72 are empty accommodation sections 72dl in which component 91 is not accommodated. Multiple accommodation sections 72d are provided at predetermined pitch intervals in a longitudinal direction of carrier tape 72 at the center portion in a width direction of base tape 72a.

Each of multiple feed holes 72e is a through hole, and is used when carrier tape 72 is conveyed in the conveyance direction (the second end side (arrow Y2 direction) in the second direction). Multiple feed holes 72e are provided at a predetermined pitch interval in the longitudinal direction of carrier tape 72 on the first end side in the width direction of base tape 72a. Cover tape 72b closes accommodation sections 72d of base tape 72a. Cover tape 72b is attached to the upper surfaces of both end portions of base tape 72a in the width direction by, for example, adhesive 72f or thermocompression bonding. Bottom tape 72c is attached to the lower surface of base tape 72a by, for example, adhesive 72f or thermocompression bonding, and prevents component 91 accommodated in accommodation section 72d from falling off.

A central portion of side plate 62 on the first end side (arrow X1 direction) in the first direction of feeder 60 is open in order to facilitate attachment and detachment of reel 70. At least one of the material of carrier tape 72, the width dimension of carrier tape 72, the width dimension of reel 70, and the diameter dimension of reel 70 is different among multiple types of reels 70, and there are multiple types of feeders 60 corresponding to multiple types of reels 70. Feeder 60 includes collection position 63, sprocket 64, and a tape peeling section.

Collection position 63 is provided on the second end side (arrow Y2 direction) in the second direction of the upper surface of feeder 60, and the component mounter collects component 91 at collection position 63. Sprocket 64 is rotatably provided on the first end side (arrow Y1 direction) in the second direction with respect to collection position 63. The teeth portion of sprocket 64 engages with feed hole 72e of carrier tape 72. Sprocket 64 is intermittently driven by a drive motor and conveys carrier tape 72 at a constant pitch. The tape peeling section can peel off cover tape 72b from base tape 72a immediately before collection position 63 to take out component 91. After passing through collection position 63, carrier tape 72 is cut by a tape cutting device provided in the component mounter.

An identification code for identifying feeder 60 is attached to each of feeders 60. Feeder 60 is provided with a feeder control section. The feeder control section stores the identification information of feeder 60 and the identification information of reel 70, and controls the component supply operation. When feeder 60 is held by feeder holding section 21, connectors thereof are fitted to each other, and the feeder control section is communicably connected to setup device 10a.

Reel attachment mechanism 22 is provided on the first end side (arrow X1 direction) in the first direction of feeder holding section 21. Reel attachment mechanism 22 changes reel 70 from a horizontal posture to a vertical posture and attaches reel 70 to feeder 60 at the work execution position using reel transfer mechanism 40. Reel attachment mechanism 22 includes pair of guide rails 22a and 22a, moving table 22b, attachment material 22c, placement area 22d, and temporary placement area 22e. Reel attachment mechanism 22 may be configured such that a mechanism that changes reel 70 from the horizontal posture to the vertical posture and a mechanism that attaches reel 70 in the vertical posture to feeder 60 are separated.

Pair of guide rails 22a and 22a extends along the first direction (arrow X direction) at a substantially central position in the second direction (arrow Y direction) of first housing 11, and is disposed in parallel to be separated from each other. Moving table 22b extends along the second direction (arrow Y direction), and is provided to straddle the upper sides of pair of guide rails 22a and 22a. As illustrated in FIGS. 1 and 2, moving table 22b moves along pair of guide rails 22a and 22a, and reciprocates between a standby position provided on the first end side (arrow X1 direction) in the first direction and feeder holding section 21 provided on the second end side (arrow X2 direction) in the first direction.

Attachment material 22c is formed in a square bar shape, and is provided to extend upward from moving table 22b. Attachment material 22c faces reel holding shaft 61 of feeder 60 at the work execution position. Specifically, attachment material 22c is provided at a position separated by a predetermined distance from a tip end portion of reel holding shaft 61 toward the first end side (arrow X1 direction) in the first direction. Attachment material 22c swings (arrow SW1 in FIG. 1) between an upright posture illustrated in FIGS. 1 and 2 and a horizontal posture in which attachment material 22c is tilted toward the second end side (arrow X2 direction) in the first direction around swing shaft 22c1 provided on moving table 22b side. Collection section 22c2 is provided on an end portion on a side different from an end portion of swing shaft 22c1 side of attachment material 22c. Collection section 22c2 detachably collects reel 70. As collection section 22c2, a claw portion inserted into the center hole of reel 70, a gripping mechanism that grips a peripheral edge of reel 70, a pickup mechanism that picks up reel 70 using negative pressure, or the like can be used.

Placement area 22d is provided on the first end side (arrow X1 direction) in the first direction in pair of guide rails 22a and 22a. In placement area 22d, reel 70 to be attached is placed in a horizontal posture. Temporary placement area 22e is provided on pair of guide rails 22a and 22a on the second end side (arrow X2 direction) in the first direction with respect to placement area 22d. In temporary placement area 22e, when reel attachment mechanism 22 changes the use order of reels 70, reels 70 are temporarily placed in the horizontal posture and the use order of reels 70 is changed. In temporary placement area 22e, an area in which multiple reels 70 can be temporarily placed is secured. Moving table 22b and attachment material 22c move above placement area 22d and temporary placement area 22e.

As illustrated in FIG. 2, tape loading mechanism 23 is provided near feeder holding section 21. Tape loading mechanism 23 loads carrier tape 72 in feeder 60 so that carrier tape 72 can be fed. For example, an articulated robot can be used as tape loading mechanism 23. Tape loading mechanism 23 of the embodiment includes articulated arm 23a, camera 23b, and multiple fingers 23c.

Articulated arm 23a can perform operations such as rotation and bending of the arm, and can adjust the positions and directions of camera 23b and multiple fingers 23c. Camera 23b is provided at a tip end portion of articulated arm 23a. Camera 23b images feeder 60 at the work execution position to detect the positions and the states of reel 70 and carrier tape 72. Multiple fingers 23c are provided side by side with camera 23b at the tip end portion of articulated arm 23a. Multiple fingers 23c can perform a moving operation, a twisting operation, and the like in addition to the operations of gripping and releasing a work target.

Multiple fingers 23c load carrier tape 72 so that feed hole 72e at a tip end portion of carrier tape 72 engages with sprocket 64, so that carrier tape 72 can be fed. Multiple fingers 23c facilitate the loading operation of carrier tape 72 by rotating reel 70 around reel holding shaft 61 as necessary. Tape loading mechanism 23 takes a retracted posture in which articulated arm 23a is bent not to hinder the attaching and detaching operation of reel 70 in a time period other than the operation time.

Reel detachment mechanism 24 is provided on the first end side (arrow X1 direction) in the first direction of feeder holding section 21, and is disposed above reel attachment mechanism 22. Reel detachment mechanism 24 detaches reel 70 from feeder 60 at the work execution position. Reel detachment mechanism 24 includes guide rail 24a, moving table 24b, detachment material 24c, and retrieval box 24d.

Guide rail 24a is provided in the vicinity of the ceiling of first housing 11, and is formed to extend along the second direction (arrow Y direction). Moving table 24b is formed to extend along the first direction (arrow X direction), and is provided below guide rail 24a. As illustrated in FIGS. 1 and 2, moving table 24b moves along guide rail 24a and reciprocates between a standby position provided on the second end side (arrow Y2 direction) in the second direction and feeder holding section 21.

Detachment material 24c is formed of a thick plate-shaped member longer than moving table 24b, and is provided below moving table 24b to extend along the first direction (arrow X direction). Detachment material 24c swings (arrow SW2 in FIG. 1) between a horizontal posture illustrated in FIGS. 1 and 2 and a vertical posture in which detachment material 24c is tilted downward around swing shaft 24c1provided on the second end side (arrow X2 direction) in the first direction of moving table 24b. Collection section 24c2 is provided on an end portion on a side different from the end portion on swing shaft 24c1 side of detachment material 24c. Collection section 24c2 detachably collects reel 70. The collecting method of collection section 24c2 may be the same as or different from collection section 22c2 of reel attachment mechanism 22.

Retrieval box 24d is provided to be positioned below detachment material 24c when moving table 24b is moved to the standby position. Retrieval box 24d retrieves multiple detached reels 70. Retrieval box 24d is formed in a box shape opening upward. Accordingly, retrieval box 24d can retrieve reel 70 that falls when collection section 24c2 of detachment material 24c releases reel 70.

Reel supply section 30 includes reel holding section 31 that is detachably provided. Pair of guide plates 12a and 12a extending along the second direction (arrow Y direction) is provided on the first end side (arrow X1 direction) in the first direction and the second end side (arrow X2 direction) in the first direction of the upper surface of base 12. Reel holding section 31 is placed between pair of guide plates 12a and 12a of base 12. As illustrated in FIG. 2, surfaces of pair of guide plates 12a and 12a facing each other on the first end side (arrow Y1 direction) in the second direction are formed in a tapered shape, and a separation distance on the first end side (arrow Y1 direction) in the second direction is longer than that on the second end side (arrow Y2 direction) in the second direction. This facilitates the work of inserting reel holding section 31 toward base 12 from the first end side (arrow Y1 direction) in the second direction.

Reel holding section 31 stacks and holds multiple reels 70 in a horizontal posture. Reel 70 is not limited to an unused reel, and may be a reel in use in which carrier tape 72 has been used halfway. Reel holding section 31 includes circular plate-shaped holding plate 31a provided horizontally, and round rod-shaped holding shaft 31b provided upward from the center of holding plate 31a and penetrating through the center hole of reel 70. Accordingly, reel holding section 31 can hold multiple reels 70 in a state where holding shaft 31b penetrates through the center holes of multiple reels 70 even when reels 70 having at least one of different diameter and different width dimension coexist, and reels 70 can be easily taken out. Identification code 31c is attached to an upper surface of holding plate 31a. Identification code 31c includes information for specifying reel holding section 31.

For example, the worker procures multiple reels 70 based on work instruction data, and performs a stacking work of stacking multiple reels 70 on reel holding section 31. The work instruction data indicates a work content of the setup work performed by setup device 10a. That is, in the work instruction data, the type information of multiple reels 70 required with the progress of the production of board products by the component mounter is associated with the type information of multiple feeders 60 applicable to reels 70. A known automated guided vehicle or the like may also be used to convey multiple reels 70.

Reel transfer mechanism 40 is provided on plate base 12b extending from the bottom portion of base 12 to the second end side (arrow X2 direction) in the first direction. Reel transfer mechanism 40 includes support column 41, arm 42, and collection section 43. Support column 41 stands upward in the vertical direction on the second end side (arrow Y2 direction) in the second direction of plate base 12b. Arm 42 is provided to be liftable and lowerable with respect to support column 41. Further, arm 42 is provided to be rotatable on a horizontal plane around rotation shaft 44 close to support column 41.

Collection section 43 is provided to be extendable and contractible with respect to arm 42. Collection section 43 detachably collects reel 70. The collecting method of collection section 43 may be the same as or different from the collecting method of collection section 22c2 of reel attachment mechanism 22 and collection section 24c2 of reel detachment mechanism 24. Collection section 43 is provided with a code reader. The code reader reads identification code 31c of reel holding section 31. Further, the code reader can read the identification code of uppermost reel 70.

Reel transfer mechanism 40 functions as a part of reel attachment mechanism 22. Specifically, reel transfer mechanism 40 takes out reel 70 from reel holding section 31 by driving arm 42 and collection section 43. Further, reel transfer mechanism 40 places taken out reel 70 in placement area 22d or temporary placement area 22e in the state of the horizontal posture by driving arm 42 and collection section 43. Reel transfer mechanism 40 sequentially uses multiple reels 70 stacked on reel holding section 31 from the uppermost.

Feeder supply section 50 includes feeder accommodation section 51 that is detachably provided and feeder conveyance section 52. As illustrated in FIG. 2, storage space 13a in the upper portion of second housing 13 is open on the first end side (arrow Y1 direction) in the second direction, and can store multiple (for example, two in FIG. 2) feeder accommodation sections 51 arranged along the first direction (arrow X direction). As illustrated in FIG. 1, multiple roller conveyors 13b extending along the first direction (arrow X direction) are provided on a bottom surface defining storage space 13a, so that a storage operation of feeder accommodation section 51 is facilitated.

Feeder accommodation section 51 is formed in a box shape whose first end side (arrow Y1 direction) in the second direction is opened. Multiple slots having the same shape as slot 21b of feeder holding section 21 are formed on the bottom surface of feeder accommodation section 51. Feeder accommodation section 51 can accommodate multiple feeders 60 in a vertical posture arranged along the first direction (arrow X direction). When multiple feeders 60 are accommodated in feeder accommodation section 51 and feeder accommodation section 51 is properly stored in storage space 13a, the connectors of feeder 60 and feeder accommodation section 51 are fitted to each other, and multiple feeder control sections are communicably connected to setup device 10a.

An identification code for identifying feeder accommodation section 51 is attached to feeder accommodation section 51. For example, the worker procures multiple feeders 60 to be used based on the work instruction data, and performs the accommodation work of accommodating feeders 60 in feeder accommodation section 51. The number of feeder accommodation sections 51 that can be accommodated in storage space 13a may be one or three or more. A known automated guided vehicle or the like can also be used to convey multiple feeders 60.

Guide rail 13c is provided in a lower portion on the first end side (arrow Y1 direction) in the second direction of storage space 13a of second housing 13. Guide rail 13c is provided in storage space 13a over substantially the entire first direction (arrow X direction), and is provided to extend to the first end side (arrow Y1 direction) in the second direction of feeder holding section 21. Guide rail 13c is provided with feeder conveyance section 52. Feeder conveyance section 52 moves along guide rail 13c and reciprocates between feeder accommodation section 51 and feeder holding section 21.

Feeder conveyance section 52 is formed in a box shape having an opening portion on the second end side (arrow Y2 direction) in the second direction. Feeder conveyance section 52 includes a built-in space that temporarily incorporates feeder 60, and a feeder operation mechanism that conveys feeder 60 into the built-in space through the opening portion and conveys feeder 60 out of the built-in space. Accordingly, feeder conveyance section 52 can convey feeder 60 out of feeder accommodation section 51 and feeder holding section 21, and can convey feeder 60 into feeder accommodation section 51 and feeder holding section 21. An openable and closable safety fence is provided on the first end side (arrow Y1 direction) in the second direction of reel supply section 30 and feeder supply section 50, and the approach of the worker to reel supply section 30 and feeder supply section 50 is suppressed.

### 1-2. Control Example of Setup Device 10a

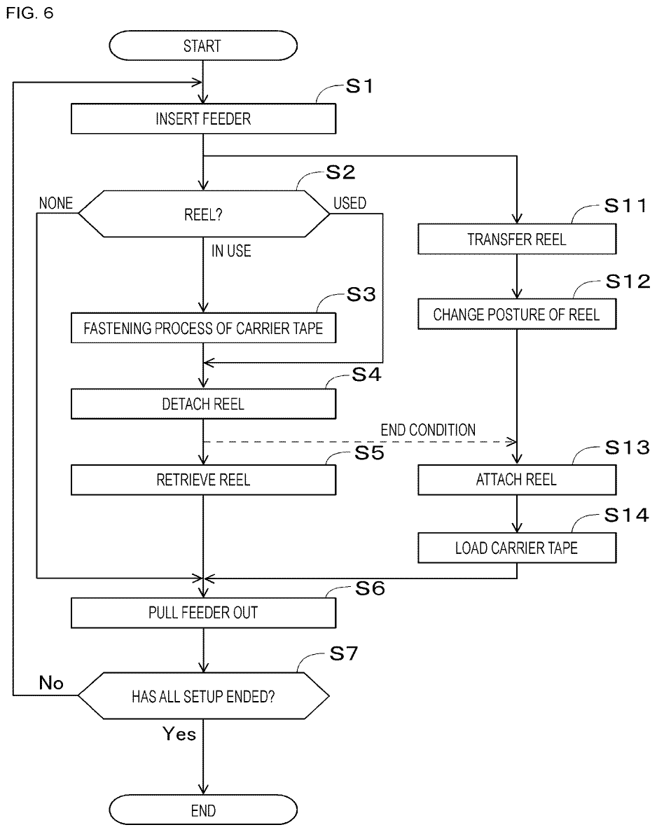

Setup device 10a causes feeder conveyance section 52 to convey feeder 60 corresponding to uppermost reel 70 of reel holding section 31 (step S1 illustrated in FIG. 6). Feeder conveyance section 52 pulls out and incorporates feeder 60 from feeder accommodation section 51, moves to feeder holding section 21, and inserts incorporated feeder 60 into feeder holding section 21. Accordingly, feeder 60 is held at the work execution position, and the identification code of feeder 60 is read.

When there is no feeder 60 applicable to uppermost reel 70 of reel holding section 31, reel 70 is placed in temporary placement area 22e by reel transfer mechanism 40. The above-described placement is repeated until applicable feeder 60 is present, and feeder 60 corresponding to uppermost reel 70 of reel holding section 31 is inserted into feeder holding section 21. After the control illustrated in step S1, in setup device 10a, a first-series control illustrated in steps S2 to S5 and a second-series control illustrated in steps S11 to S14 are executed in parallel.

In the first-series control, setup device 10a confirms the state of reel 70 based on the read identification code of feeder 60 or the read identification code of reel 70, and changes the control according to the state of reel 70 (step S2). Specifically, when feeder 60 is used in the component mounter in advance, there is a possibility that reel 70 in use in which carrier tape 72 has been used halfway is provided in feeder 60. In this case, tape loading mechanism 23 performs a fastening process of fixing the tip end portion of carrier tape 72 with a tape or the like to suppress slack of carrier tape 72 (step S3). At this time, tape loading mechanism 23 can wind carrier tape 72 onto reel 70 as necessary. Thereafter, tape loading mechanism 23 takes a retracted posture in which articulated arm 23a is bent.

Next, reel detachment mechanism 24 detaches reel 70 from feeder 60 (step S4). Specifically, moving table 24b moves from the standby position to feeder holding section 21. Then, when detachment material 24c is swung from the horizontal posture to the vertical posture, collection section 24c2 comes into contact with reel 70 and collects reel 70. Then, when detachment material 24c returns from the vertical posture to the horizontal posture, collection section 24c2 pulls out reel 70 from reel holding shaft 61 and holds reel 70 in the horizontal posture. In this case, setup device 10a deletes the identification information of reel 70 from the storage section of the feeder control section of feeder 60. Further, setup device 10a transmits the identification information of feeder 60 from which reel 70 has been detached to a higher-level management device. At this time, setup device 10a may transmit the identification information of detached reel 70 together with the identification information of feeder 60 to the higher-level management device.

Next, reel detachment mechanism 24 retrieves reel 70 (step S5). Specifically, first, moving table 24b moves from feeder holding section 21 to the standby position. Then, collection section 24c2 releases reel 70. Thus, released reel 70 falls into retrieval box 24d and is retrieved. When reel 70 is retrieved, the first-series control is in a standby state until the second-series control ends.

There is a possibility that feeder 60 is provided with used reel 70 in which all of carrier tape 72 has been used (step S2). In this case, in the first-series control, the control illustrated in step S3 is omitted, and the controls illustrated in step S4 and step S5 are executed. There is a possibility that feeder 60 is not provided with reel 70 (step S2). In this case, in the first-series control, the controls illustrated in steps S3 to S5 are omitted.

In the second-series control, reel transfer mechanism 40 collects uppermost reel 70 of reel holding section 31 using collection section 43, and places reel 70 in placement area 22d (step S11). Then, reel transfer mechanism 40 returns collection section 43 to above reel holding section 31. When there is no applicable feeder 60, reel transfer mechanism 40 places reel 70 in temporary placement area 22e.

Next, reel attachment mechanism 22 changes the posture of reel 70 in placement area 22d (step S12). Specifically, first, attachment material 22c is changed from the upright posture to the horizontal posture, and collection section 22c2 comes into contact with reel 70 and collects reel 70. Then, attachment material 22c is returned from the horizontal posture to the upright posture, and collection section 22c2 changes reel 70 from the horizontal posture to the vertical posture and holds reel 70. When reel 70 in temporary placement area 22e is used, moving table 22b moves to the second end side (arrow X2 direction) in the first direction by a predetermined distance before attachment material 22c shifts from the upright posture to the horizontal posture. The second-series control is in a standby state until an end condition indicating the completion of the control of step S4 of the first-series is satisfied. This avoids interference between reel attachment mechanism 22 and reel detachment mechanism 24.

When the end condition described above is satisfied, reel attachment mechanism 22 attaches reel 70 to feeder 60 (step S13). Specifically, in a state where collection section 22c2 holds reel 70 in the vertical posture, moving table 22b moves to feeder holding section 21. Accordingly, reel 70 moves toward reel holding shaft 61 and is attached to reel holding shaft 61. The movement of moving table 22b can be performed simultaneously with the movement of moving table 24b to the standby position.

When the attachment of reel 70 ends, setup device 10a stores the identification information of reel 70 in the feeder control section of feeder 60 to which reel 70 is attached. Further, setup device 10a transmits the identification information of feeder 60 and the identification information of reel 70 provided in feeder 60 to the higher-level management device in association with each other. Moving table 22b returns to the standby position. Next, tape loading mechanism 23 loads carrier tape 72 until feed hole 72e of carrier tape 72 engages with the teeth portion of sprocket 64 (step S14).

When the first-series control and the second-series control end, feeder conveyance section 52 pulls out feeder 60 from feeder holding section 21, incorporates feeder 60 therein, moves feeder 60 to feeder accommodation section 51, and inserts incorporated feeder 60 into feeder accommodation section 51 (step S6). Thus, the setup work for one feeder 60 ends. Setup device 10a determines whether the setup work for all feeders 60 has ended (step S7). When the setup work for all feeders 60 has ended (Yes in step S7), the control by setup device 10a temporarily ends. When the setup work for all feeders 60 has not ended (No in step S7), the control by setup device 10a returns to the control illustrated in step S1, and the control described above is repeated until the setup work for all feeders 60 ends.

When the control by setup device 10a ends, for example, the worker conveys feeder accommodation section 51 accommodating feeder 60 that has been set up to the component mounter, and performs the setup change of feeder 60. When reel 70 is placed in temporary placement area 22e, when the worker accommodates feeder 60 applicable to reel 70 in feeder accommodation section 51, reel 70 becomes usable. Further, reel 70 left unused in temporary placement area 22e is returned to reel holding section 31 by reel transfer mechanism 40 and retrieved by the worker. Further, the above-described conveyance work by the worker can also be automated using a known automated guided vehicle or the like.

### 1-3. Configuration Example of Mechanism Related to Replacement of Drum 80

Feeder 60 illustrated in FIG. 3 includes drum 80. Cover tape 72b peeled off from carrier tape 72 is wound onto drum 80. When a predetermined amount of cover tape 72b is wound onto drum 80, it is necessary to replace drum 80. Kitting device 10 includes drum replacement unit 83. Drum replacement unit 83 replaces used drum 80a wound with cover tape 72b peeled off from carrier tape 72 with replacement drum 80b onto which cover tape 72b can be wound. Drum 80 with cover tape 72b not wound at all, or drum 80 with less than the predetermined amount of cover tape 72b wound, is included in replacement drum 80b.

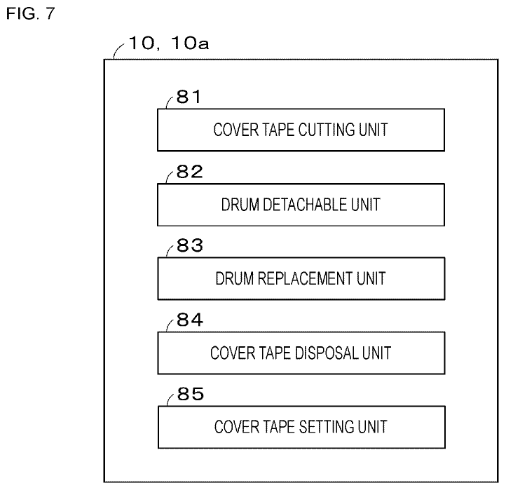

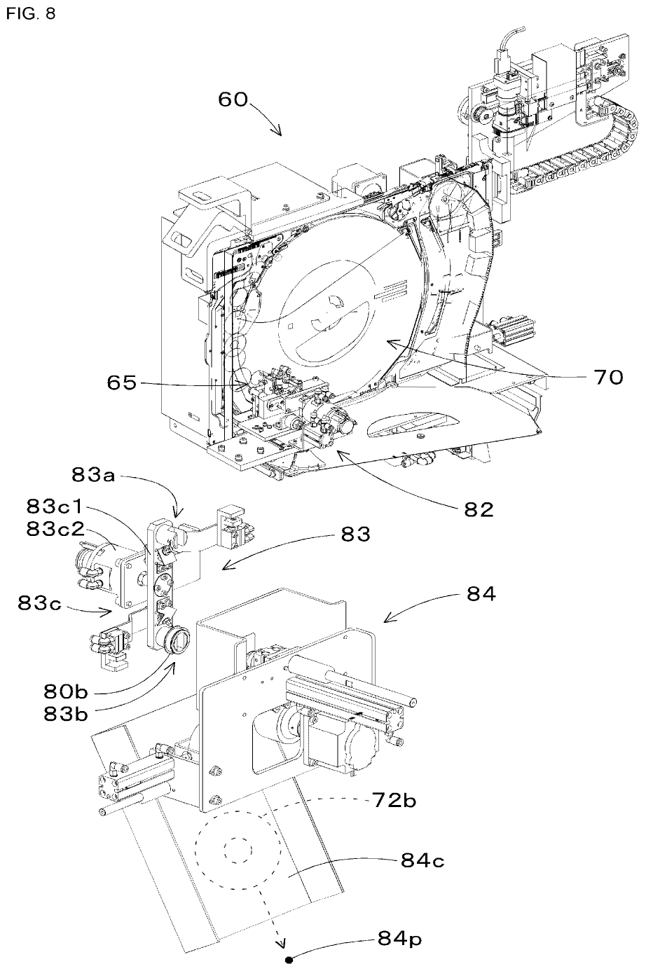

Kitting device 10 may include cover tape cutting unit 81. Kitting device 10 may include drum detachable unit 82. Further, kitting device 10 may include cover tape disposal unit 84. Kitting device 10 may include cover tape setting unit 85. As illustrated in FIGS. 7 and 8, kitting device 10 of the embodiment includes cover tape cutting unit 81, drum detachable unit 82, drum replacement unit 83, cover tape disposal unit 84, and cover tape setting unit 85.

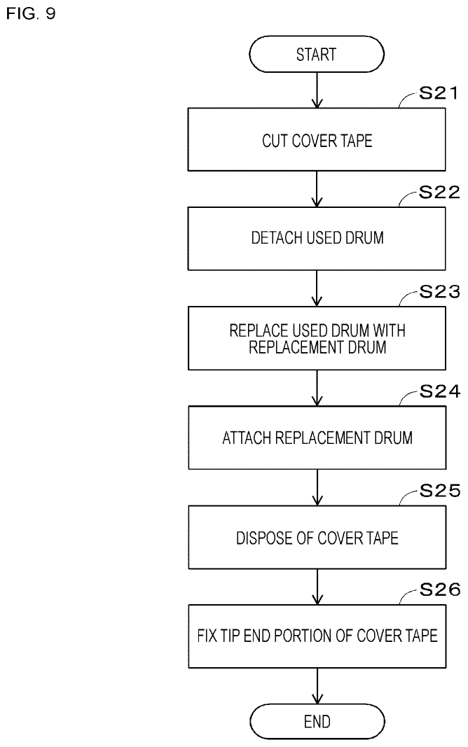

Kitting device 10 of the embodiment performs control according to the flowchart illustrated in FIG. 9. Cover tape cutting unit 81 performs the process illustrated in step S21. Drum detachable unit 82 performs the process illustrated in step S22 and step S24. Drum replacement unit 83 performs the process illustrated in step S23. Cover tape disposal unit 84 performs the process illustrated in step S25. Cover tape setting unit 85 performs the process illustrated in step S26.

### 1-3-1. Cover Tape Cutting Unit 81

Cover tape cutting unit 81 cuts cover tape 72b on reel 70 set in feeder 60 so that used drum 80a can be detached from feeder 60 (step S21 illustrated in FIG. 9). Cover tape cutting unit 81 needs only to be configured so that used drum 80a can be detached, as described above, and may take various forms.

For example, cover tape cutting unit 81 includes a cover tape holding section and a cover tape cutting section. The cover tape holding section holds cover tape 72b on the side of used drum 80a (referred to as drum 80 in FIG. 3) with respect to the cutting position of cover tape 72b on reel 70 set in feeder 60 (for example, cutting position CTO illustrated in FIG. 3). The cutting position can be set at any position between the peeling position of cover tape 72b and used drum 80a.

The cover tape holding section needs only to be capable of holding cover tape 72b, and a known gripping mechanism can be used. The cover tape holding section may use, for example, multiple fingers 23c of tape loading mechanism 23. The cover tape cutting section cuts cover tape 72b at the cutting position. The cover tape cutting section needs only to be capable of cutting cover tape 72b, and a known cutting mechanism can be used.

After cover tape 72b is held by the cover tape holding section, cover tape cutting unit 81 can cut cover tape 72b by the cover tape cutting section. Further, cover tape cutting unit 81 can cut cover tape 72b by the cover tape cutting section simultaneously while holding cover tape 72b by the cover tape holding section. Tape loading mechanism 23 may perform a fastening process of fixing the cutting section of cover tape 72b with a tape or the like to suppress slack of cover tape 72b.

### 1-3-2. Drum Detachable Unit 82

Drum detachable unit 82 detaches used drum 80a from feeder 60 (step S22 illustrated in FIG. 9). Drum detachable unit 82 needs only to be capable of detaching used drum 80a from feeder 60, and may take various forms.

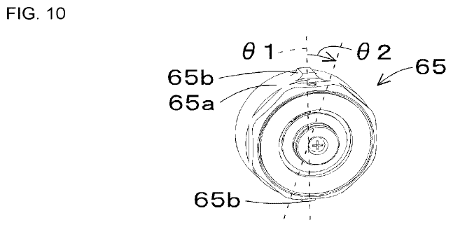

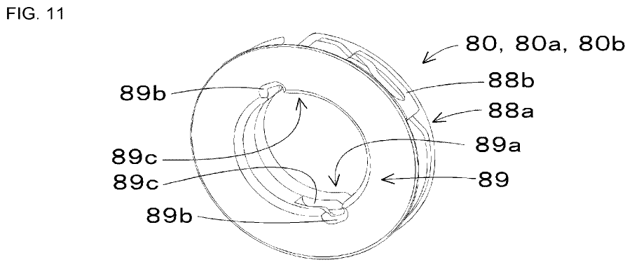

For example, as illustrated in FIG. 10, feeder 60 includes feeder-side holding section 65 that holds used drum 80a. As illustrated in FIG. 11, used drum 80a includes held section 89 held by feeder-side holding section 65. Used drum 80a is held in feeder 60 in a state where held section 89 enters feeder-side holding section 65 at first angle θ1 defined with respect to feeder-side holding section 65, and then is rotated by second angle θ2 in a predetermined direction.

Specifically, feeder-side holding section 65 includes multiple (two in FIG. 10) protruding portions 65b and 65b protruding radially outward from outer peripheral portion 65a. Held section 89 is provided on inner peripheral portion 89a of annular-shaped used drum 80a and includes multiple (two) recessed portions 89b and 89b and multiple (two) groove portions 89c and 89c. Multiple (two) recessed portions 89b and 89b are recessed radially outward to be able to enter multiple (two) protruding portions 65b and 65b of feeder-side holding section 65.

Multiple (two) groove portions 89c and 89c are formed in the circumferential direction over an angular range extending from first angle θ1, at which multiple (two) recessed portions 89b and 89b enter multiple (two) protruding portions 65b and 65b, to predetermined second angle θ2. Used drum 80a is held in feeder 60 in a state where multiple (two) recessed portions 89b and 89b of held section 89 enter multiple (two) protruding portions 65b and 65b at first angle θ1 defined with respect to feeder-side holding section 65, and then are rotated by second angle θ2 in a predetermined direction (counterclockwise as viewed from the front side of paper in FIG. 10). Replacement drum 80b includes a mechanism similar to that of used drum 80a, and what has been described for used drum 80a can similarly be applied to replacement drum 80b.

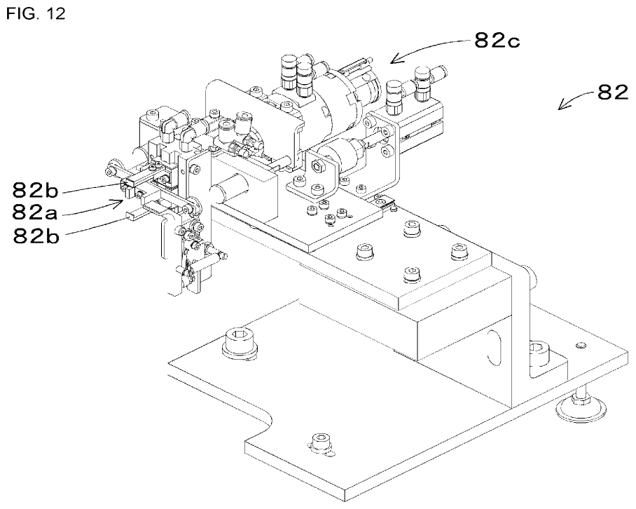

Drum detachable unit 82 rotates held section 89 by second angle θ2 in a direction opposite to the predetermined direction (in the example above, clockwise as viewed from the front side of the paper) with respect to feeder-side holding section 65 to release the holding of used drum 80a, and detaches used drum 80a from feeder 60. Specifically, as illustrated in FIG. 12, drum detachable unit 82 includes fixing section 82a, multiple (two) chuck portions 82b and 82b, and drive section 82c.

Feeder-side holding section 65 is rotatable in order to wind cover tape 72b, which is peeled off, together with the conveyance of carrier tape 72, onto drum 80. Therefore, when attaching and detaching drum 80 (used drum 80a and replacement drum 80b), it is necessary to fix feeder-side holding section 65. Fixing section 82a holds feeder-side holding section 65 and restricts the rotation of feeder-side holding section 65. Multiple (two) chuck portions 82b and 82b are claw-shaped members and grip outer peripheral portion 88a of annular-shaped used drum 80a.

Drive section 82c moves fixing section 82a to feeder-side holding section 65 and causes fixing section 82a to hold feeder-side holding section 65. Further, drive section 82c moves multiple (two) chuck portions 82b and 82b to used drum 80a, and causes multiple (two) chuck portions 82b and 82b to grip outer peripheral portion 88a of used drum 80a. Then, drive section 82c rotates multiple (two) chuck portions 82b and 82b by second angle θ2 in a direction opposite to the predetermined direction (clockwise as viewed from the front side of the paper) to release the holding of used drum 80a.

Thereafter, drive section 82c separates multiple (two) chuck portions 82b and 82b from used drum 80a and detaches used drum 80a from feeder 60. In addition, drive section 82c separates fixing section 82a from feeder-side holding section 65 and releases the holding of feeder-side holding section 65. As a result, used drum 80a is detached from feeder 60.

### 1-3-3. Drum Replacement Unit 83

Drum replacement unit 83 replaces used drum 80a with replacement drum 80b (step S23 illustrated in FIG. 9). Drum replacement unit 83 needs only to be capable of replacing used drum 80a with replacement drum 80b, and may take various forms.

For example, as illustrated in FIG. 8, drum replacement unit 83 includes first holding section 83a, second holding section 83b, and arrangement change section 83c. First holding section 83a can hold used drum 80a. First holding section 83a includes a mechanism similar to feeder-side holding section 65, and can hold used drum 80a detached from feeder 60 by drum detachable unit 82. Drum detachable unit 82 can be moved to drum replacement unit 83 by, for example, an XY table (a moving mechanism movable in the first direction (arrow X direction) and the second direction (arrow Y direction)), and similarly to feeder 60, can perform the attachment and detachment of used drum 80a and replacement drum 80b.

Second holding section 83b can hold replacement drum 80b. Second holding section 83b includes a mechanism similar to that of feeder-side holding section 65 and first holding section 83a, and, as illustrated in FIG. 8, replacement drum 80b is held in advance. Arrangement change section 83c can change the arrangement of first holding section 83a and second holding section 83b. For example, arrangement change section 83c includes base section 83c1 and rotating section 83c2. Base section 83c1 is provided with first holding section 83a and second holding section 83b. Rotating section 83c2 is a known rotating mechanism such as an electric motor, and can rotate base section 83c1.

After used drum 80a detached from feeder 60 by drum detachable unit 82 is held by first holding section 83a, drum replacement unit 83 changes the arrangement of first holding section 83a and second holding section 83b by arrangement change section 83c. Drum replacement unit 83 then replaces used drum 80a with replacement drum 80b held in second holding section 83b in advance. Specifically, when rotating section 83c2 rotates base section 83c1, the arrangement of first holding section 83a and second holding section 83b is changed, and used drum 80a and replacement drum 80b are replaced.

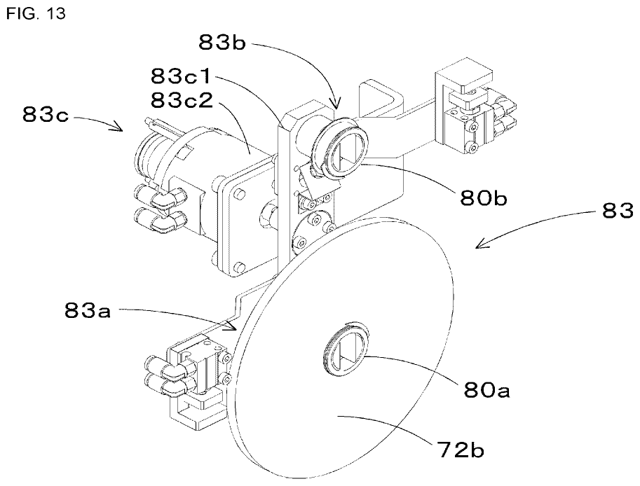

For example, arrangement change section 83c can reverse the arrangement of first holding section 83a and second holding section 83b by rotating 180 degrees from a state where used drum 80a is held by first holding section 83a. Drum replacement unit 83 illustrated in FIG. 8 illustrates a state before the rotation, and drum replacement unit 83 illustrated in FIG. 13 illustrates a state after a 180-degree rotation. In drum replacement unit 83 illustrated in FIG. 8, illustration of cover tape 72b is omitted for convenience of description of the mechanism.

By the 180-degree rotation described above, used drum 80a held by first holding section 83a at the upper part of the paper in FIG. 8 moves to the position of second holding section 83b before the rotation by rotating 180 degrees. Replacement drum 80b held by second holding section 83b at the lower part of the paper in FIG. 8 moves to the position of first holding section 83a before the rotation by rotating 180 degrees. Accordingly, drum detachable unit 82 can receive replacement drum 80b at the same position as the position where used drum 80a is held by first holding section 83a.

Drum detachable unit 82 can receive replacement drum 80b from second holding section 83b in the same manner as used drum 80a. Further, drum detachable unit 82 can move to feeder 60, and can perform attachment work of attaching replacement drum 80b replaced by drum replacement unit 83 to feeder 60 (step S24 illustrated in FIG. 9). Specifically, drive section 82c moves fixing section 82a to feeder-side holding section 65 and causes fixing section 82a to hold feeder-side holding section 65.

Drive section 82c moves multiple (two) chuck portions 82b and 82b to feeder-side holding section 65 such that multiple (two) recessed portions 89b and 89b of held section 89 of replacement drum 80b enter multiple (two) protruding portions 65b and 65b at first angle θ1 defined with respect to feeder-side holding section 65. Then, drive section 82c rotates multiple (two) chuck portions 82b and 82b by second angle θ2 in a predetermined direction (counterclockwise as viewed from the front side of the paper in FIG. 10) to hold replacement drum 80b.

Thereafter, drive section 82c separates multiple (two) chuck portions 82b and 82b from replacement drum 80b. In addition, drive section 82c separates fixing section 82a from feeder-side holding section 65 and releases the holding of feeder-side holding section 65. As a result, replacement drum 80b is attached to feeder 60.

When the attachment work of attaching replacement drum 80b replaced by drum replacement unit 83 to feeder 60 starts only after the disposal work of disposing of cover tape 72b wound onto used drum 80a is completed, the attachment work may be delayed. Drum detachable unit 82 may start the attachment work before a start of disposal work or simultaneously with the start of the disposal work. This improves the work efficiency compared to the case where the attachment work starts after the disposal work is completed.

### 1-3-4. Cover Tape Disposal Unit 84

Cover tape disposal unit 84 disposes of cover tape 72b wound onto used drum 80a (step S25 illustrated in FIG. 9). Cover tape disposal unit 84 needs only to be capable of disposing of cover tape 72b, and may take various forms.

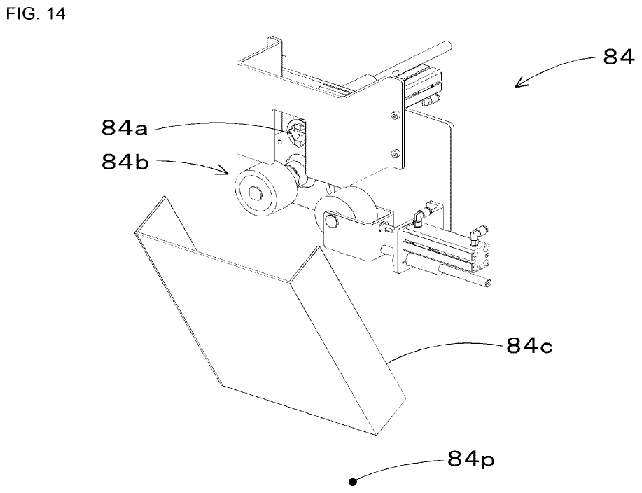

For example, as illustrated in FIGS. 8 and 14, cover tape disposal unit 84 includes disposal-side holding section 84a, detachment section 84b, and guide portion 84c. Disposal-side holding section 84a can hold used drum 80a replaced by drum replacement unit 83. Detachment section 84b can detach cover tape 72b from used drum 80a held by disposal-side holding section 84a.

Disposal-side holding section 84a needs only to be capable of holding used drum 80a, and may take various forms. Similarly, detachment section 84b needs only to be capable of detaching cover tape 72b from used drum 80a, and may take various forms. For example, detachment section 84b can push out cover tape 72b in a state in which disposal-side holding section 84a holds used drum 80a. Further, disposal-side holding section 84a and detachment section 84b can also use the gripping mechanism and the attachment/detachment mechanism described above.

Guide portion 84c is a member inclined with respect to the vertical direction, and guides cover tape 72b detached by detachment section 84b toward disposal position 84p. For example, as illustrated in FIG. 2, kitting device 10 includes retrieval box 84g that retrieves cover tape 72b at disposal position 84p. Retrieval box 84g is formed in a box shape opening upward. Retrieval box 84g can retrieve cover tape 72b that is guided and falling by guide portion 84c. In FIG. 2, cover tape cutting unit 81, drum detachable unit 82, drum replacement unit 83, cover tape disposal unit 84, and cover tape setting unit 85 are provided between tape loading mechanism 23 and temporary placement area 22e. Disposal position 84p is provided on the second end side (arrow X2 direction) in the first direction with respect to reel holding section 31.

Cover tape disposal unit 84 moves above disposal position 84p when disposing of cover tape 72b. For example, cover tape disposal unit 84 can be moved above disposal position 84p by XY table (moving mechanism movable in the first direction (arrow X direction) and the second direction (arrow Y direction)). As illustrated in FIG. 8, guide portion 84c is inclined such that cover tape 72b detached by detachment section 84b falls toward retrieval box 84g.

Further, it is preferable for cover tape disposal unit 84 to perform the disposal work of disposing of cover tape 72b in parallel with the attachment work of attaching replacement drum 80b replaced by drum replacement unit 83 to feeder 60. Accordingly, drum replacement unit 83 can prepare replacement drum 80b before the next replacement. Drum replacement unit 83 can replace used drum 80a with replacement drum 80b while circulating at least two drums 80 (used drum 80a and replacement drum 80b).

### 1-3-5. Cover Tape Setting Unit 85

After replacement drum 80b replaced by drum replacement unit 83 is attached to feeder 60, cover tape setting unit 85 sets the tip end portion of cover tape 72b on reel 70 set in feeder 60 to replacement drum 80b (step S26 illustrated in FIG. 9).

As illustrated in FIG. 11, cover tape fixing section 88b is provided on outer peripheral portion 88a of replacement drum 80b. Cover tape fixing section 88b is formed in a flange shape, and the tip end portion of cover tape 72b can be wound and fixed. Cover tape setting unit 85 can fix the tip end portion of cover tape 72b on reel 70 set in feeder 60 to cover tape fixing section 88b. For example, cover tape setting unit 85 can fix the tip end portion of cover tape 72b using the cover tape holding section of cover tape cutting unit 81. Cover tape setting unit 85 can also fix the tip end portion of cover tape 72b using multiple fingers 23c of tape loading mechanism 23.

### 1-3-6. Other Embodiments

Kitting device 10 of the embodiment is setup device 10a configured to automatically set reel in feeder 60 such that component 91 is capable of being supplied from feeder 60. Kitting device includes cover tape cutting unit 81, drum detachable unit 82, drum replacement unit 83, cover tape disposal unit 84, and cover tape setting unit 85, and the processes described above are automated.

Kitting device 10 can cause the worker to perform at least one of the processes of cover tape cutting unit 81, drum detachable unit 82, drum replacement unit 83, cover tape disposal unit 84, and cover tape setting unit 85. In this case, kitting device 10 can omit a unit that executes the process to be performed by the worker. The matters described in the present description can be selectively adopted or omitted, and can be appropriately combined.

### 2. Example of Effect of Embodiment

With kitting device 10, used drum 80a can be replaced with replacement drum 80b.

### REFERENCE SIGNS LIST

10: kitting device, 10a: setup device, 60: feeder, 65: feeder-side holding section, 70: reel, 72: carrier tape, 72b: cover tape, 80a: used drum, 80b: replacement drum, 81: cover tape cutting unit, 82: drum detachable unit, 83: drum replacement unit, 83a: first holding section, 83b: second holding section, 83c: arrangement change section, 84: cover tape disposal unit, 84a: disposal-side holding section, 84b: detachment section, 84c: guide portion, 84g: retrieval box, 84p: disposal position, 85: cover tape setting unit, 89: held section, 91: component, θ1: first angle, θ2: second angle.

1. A kitting device for setting a reel, onto which a carrier tape configured to accommodate a component is wound, in a feeder, the kitting device comprising
a drum replacement unit configured to replace a used drum, onto which a cover tape peeled off from the carrier tape is wound, with a replacement drum onto which the cover tape is capable of being wound.

2. The kitting device according to claim 1, further comprising
a cover tape cutting unit configured to cut the cover tape of the reel set in the feeder so that the used drum is detachable from the feeder.

3. The kitting device according to claim 1, further comprising
a drum detachable unit configured to detach the used drum from the feeder.

4. The kitting device according to claim 3,
wherein the feeder includes a feeder-side holding section configured to hold the used drum,
the used drum includes a held section held by the feeder-side holding section, and the used drum is held in the feeder in a state where the held section enters the feeder-side holding section at a first angle defined with respect to the feeder-side holding section, and then is rotated by a second angle in a predetermined direction, and
the drum detachable unit rotates the held section by the second angle in a direction opposite to the predetermined direction with respect to the feeder-side holding section to release holding of the used drum, and detaches the used drum from the feeder.

5. The kitting device according to claim 3,
wherein the drum replacement unit includes
a first holding section capable of holding the used drum,
a second holding section capable of holding the replacement drum, and
an arrangement change section capable of changing an arrangement of the first holding section and the second holding section, and
after the used drum detached from the feeder by the drum detachable unit is held by the first holding section, the drum replacement unit changes the arrangement of the first holding section and the second holding section by the arrangement change section, and replaces the used drum with the replacement drum held by the second holding section in advance.

6. The kitting device according to claim 5, wherein the arrangement change section reverses the arrangement of the first holding section and the second holding section by rotating 180 degrees from a state where the used drum is held by the first holding section.

7. The kitting device according to claim 3, wherein the drum detachable unit starts attachment work of attaching the replacement drum replaced by the drum replacement unit to the feeder before a start of disposal work of disposing of the cover tape wound onto the used drum or simultaneously with the start of the disposal work.

8. The kitting device according to claim 1, further comprising a cover tape disposal unit configured to dispose of the cover tape wound onto the used drum.

9. The kitting device according to claim 8,
wherein the cover tape disposal unit includes
a disposal-side holding section capable of holding the used drum replaced by the drum replacement unit,
a detachment section configured to detach the cover tape from the used drum held by the disposal-side holding section, and
a guide portion which is a member inclined with respect to a vertical direction and guides the cover tape detached by the detachment section toward a disposal position.

10. The kitting device according to claim 9,
wherein the kitting device includes a retrieval box configured to retrieve the cover tape at the disposal position,
the cover tape disposal unit moves above the disposal position when disposing of the cover tape, and
the guide portion is inclined such that the cover tape detached by the detachment section falls toward the retrieval box.

11. The kitting device according to claim 8, wherein the cover tape disposal unit performs disposal work of disposing of the cover tape in parallel with attachment work of attaching the replacement drum replaced by the drum replacement unit to the feeder.

12. The kitting device according to claim 1, further comprising
a cover tape setting unit configured to, after the replacement drum replaced by the drum replacement unit is attached to the feeder, set a tip end portion of the cover tape of the reel set in the feeder to the replacement drum.

13. The kitting device according to claim 1, wherein the kitting device is a setup device configured to automatically set the reel in the feeder such that the component is capable of being supplied from the feeder.
